(19) United States
(12) Patent Application Publication
(10) Pub. No.: US 2023/0268399 A1
(43) Pub. Date: Aug. 24, 2023

(54) LOW CONTACT RESISTANCE UNSILICIDES FOR SEMICONDUCTOR APPLICATIONS

(71) Applicant: Applied Materials, Inc., Santa Clara, CA (US)

(72) Inventors: Michael Haverty, Mountain View, CA (US); Avgerinos V. Gelatos, Scotts Valley, CA (US); Muthukumar Kaliappan, Fremont, CA (US)

(73) Assignee: Applied Materials, Inc., Santa Clara, CA (US)

(21) Appl. No.: 17/863,644

(22) Filed: Jul. 13, 2022

Related U.S. Application Data
(60) Provisional application No. 63/312,824, filed on Feb. 22, 2022.

(51) Int. Cl. H01L 29/40; H01L 29/49

(52) U.S. Cl. CPC H01L 29/401; H01L 29/495; H01L 29/41791

(57) ABSTRACT

Embodiments of the disclosure provide methods and electronic devices comprising a work function layer comprising a material that does not form a silicide. The electronic devices comprise a silicon layer with the work function layer thereon and a metal contact on the work function layer.

### TECHNICAL FIELD

This application claims priority to U.S. Provisional Application No. 63/312,824, filed Feb. 22, 2022, the entire disclosure of which is hereby incorporated by reference herein.

### TECHNICAL FIELD

Embodiments of the disclosure pertain to the field of electronic device manufacturing. In particular, embodiments of the disclosure are directed to electronic devices, processing systems and methods of forming electronic devices comprising low resistance contacts.

### BACKGROUND

Transistors are fundamental device elements of modern digital processors and memory devices, and have found applications in high-power electronics. Currently, there are a variety of transistor designs or types that may be used for different applications. Various transistor types include, for example, bipolar junction transistors (BJT), junction field-effect transistors (JFET), metal-oxide-semiconductor field-effect transistors (MOSFET), vertical channel or trench field-effect transistors, and superjunction or multi-drain transistors. One type of transistor that has emerged within the MOSFET family of transistors is a fin field-effect transistor (FinFET).

A FinFET can be fabricated on a bulk semiconductor substrate, e.g., a silicon substrate, and comprise a fin-like structure that runs in a length direction along a surface of the substrate and extends in a height direction normal to the substrate surface. The fin has a narrow width, e.g., less than 250 nanometers. The fin can pass through an insulating layer. A gate structure comprising a conductive gate material and gate insulator can be formed over a region of the fin. Upper portions of the fin are doped on either side of the gate structure to form source/drain regions adjacent to the gate.

FinFETs have favorable electrostatic properties for complimentary MOSFET scaling to smaller sizes. Because the fin is a three-dimensional structure, the transistors channel can be formed on three surfaces of the fin, so that the FinFET can exhibit a high current switching capability for a given surface area occupied on substrate. Since the channel and device can be raised from the substrate surface, there can be reduced electric field coupling between adjacent devices as compared to conventional planer MOSFETs.

A key challenge in semiconductor design, manufacture, and operation is contact resistance. For example, the source and drain regions of FinFET device may be eroded by the etch process for forming the source/drain contact trench, leading to increased contact resistance. A result of increased contact resistance is decreased performance of circuit devices, including transistors and other device structures formed on a semiconductor substrate.

Contact resistance is becoming a significant proportion of the overall device resistance due to scaling trends and an increase of contact area in 3D devices. The vast majority of solutions proposed to solve this problem focus on low work-function silicides. However, the Fermi energy of silicides is pinned toward the mid band gap of silicon relative to pure metals.

Therefore, there is a need for contacts with decreased contact resistance.

### SUMMARY

One or more embodiments of the disclosure are directed to methods of forming a contact. The methods comprise depositing a work function layer comprising a material that does not form a silicide.

Additional embodiments of the disclosure are directed to semiconductor devices comprising a work function layer on a silicon layer and a metal contact on the work function layer. The work function layer comprises a material that does not form a silicide.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Field effect transistors are voltage-controlled devices where its current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated IS and current entering the channel at the drain (D) is designated ID. Drain-to-source voltage is designated VDS. By applying voltage to gate (G), the current entering the channel at the drain (i.e., ID) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both be of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET, is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

One or more embodiments of the disclosure provide low work function pure metals or metal alloys that minimize contact resistance. Some embodiments of the disclosure utilize bromide and/or trimethylsilyl precursors to deposit pure In, Bi, or As. Some embodiments provide methods and/or materials for contact resistance applications of a low nMOS Schottky Barrier to replace the typical use of silicides as contacts. Due to the lack of silicide formation and subsequent risks to adhesion, nucleation, and agglomeration, an integration flow and processing scheme is provided to minimize the risks and potential alloying options to stabilize the metals for higher temperature applications. Without being bound by any particular theory of operation, it is believed that the use of indium (In), bismuth (Bi), and/or zinc (Zn) as contact metal can minimize the Schottky Barrier for nMOS devices and enable a minimum total device resistance that is useful to reduce the power of the device and increase battery life. Through the use of silicide contact materials, no product on the market has approached a Schottky Barrier as low as what is possible with pure In, Bi, or As. In addition, indium has a lower bulk resistivity than Ti-silicide, which it is believed will further reduce the impact to total device resistance.

The inventors have surprisingly found that an “unsilicide”, or a pure metal alterative to the common metals used to form silicides for contact applications (e.g., Ti, Ni, Co, lanthanides, etc.) provide excellent options for contact replacements.

Lanthanide-series elements are well-known to form low Schottky Barrier silicides. For practical use in electronic devices, a thick film (10 nm's or more) of capping materials such as TiN or W is required to protect the reactive silicides from oxidation. When these reactive silicides convert into oxides their properties change drastically and they become insulating compounds that will short out the device. These thick capping layers are not practical in advanced semiconductor node generation devices and for this reason, no semiconductor manufacture has been successful in delivering a lanthanide silicide contact metal-based device.

Some embodiments of the disclosure provide both device level contact resistance metrics (Schottky Barrier) as well as integration metrics to deposit a material that is stable and conductive after all processing steps (based on formation energies). Some embodiments provide pure metals with work functions less than titanium. Some embodiments provide materials with formation energies of metal oxides that is at least 50% less than titanium oxide. Some embodiments provide materials with formation energies of metal nitrides at least 50% less than titanium nitride. Some embodiments provide materials with formation energies of a metal silicide that is unstable.

Some embodiments of the disclosure provide materials with a work function below 4.2 eV that does not form a silicide and has a resistivity below 10 nm. In addition, zinc (Zn) and bismuth (Bi) are also secondary options with low stability or unstable silicide formation and a work function less than that of Ti. In some embodiments, zinc (Zn) provides a material with oxide formation energy that is less than half as stable as Ti-oxide, and it also forms a weakly stable silicide.

The main integration concern with these types of materials that do not form a silicide is that they do not form strong chemical bonds to silicon. Accordingly, some embodiments of the disclosure provide methods for depositing thin and conformal layers an unsilicide material. In some embodiments, a capping material such as TiN with good mechanical integrity is used.

Some embodiments of the disclosure provide methods using indium-bromide and/or indium-TMS (trimethylsilane) precursors. In some embodiments, In—In bonds are formed from the reaction of the In—Br and In-TMS precursors which are exothermic with no barrier (i.e., a spontaneous reaction).

Some embodiments incorporate some carbon into the film. Some embodiments remove or reduce the carbon content by suitable post-deposition processing.

In some embodiments, pure indium metal is formed. As used in this manner, a “pure” metal film comprises greater than or equal to 95%, 98%, 99% or 99.5% of the stated metal on an atomic basis. In some embodiments, the pure indium metal has a 100 mV Schottky Barrier based upon it's work function trend relative to Ti-silicide.

Embodiments disclosed herein include a processing system and a method of forming a contact. In various embodiments, the method includes performing the following operations in a processing system without breaking vacuum: performing a pre-clean process on an exposed surface of a source/drain region of a transistor of a substrate, the source/drain region is exposed through a trench formed in a dielectric material formed over the source/drain region, forming a silicide layer on the exposed source/drain region by an epitaxial deposition process, forming a barrier/liner layer over the silicide layer by an atomic layer deposition process, forming an anchor layer on the barrier/liner layer by a physical vapor deposition process, filling the trench with a conductor by a chemical vapor deposition process, and annealing the substrate. The integrated process can form cobalt contacts with reduced resistance and voids, thereby providing high-performance logic transistor. Embodiments disclosed herein may be useful for, but are not limited to, creating a contact with decreased contact resistance.

The foregoing broadly outlines techniques described in this disclosure. It is contemplated that the concepts of the present disclosure may be implemented for a planar transistor device or for a three-dimensional transistor device, such as fin field effect transistors (FinFETs), horizontal gate all around (HGAA) FETs, vertical gate all around (VGAA) FETs, nanowire channel FETs, strained-semiconductor devices, etc.

As used herein, the term “about” refers to a +/−10% variation from the nominal value. It is to be understood that such a variation can be included in any value provided herein.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

The metal unsilicide layer, also referred to as a work-function layer, of some embodiments comprises a low work function (WF) material that does not form silicides. In some embodiments, the low work function material forms an alloy or intermetallic material with titanium. In some embodiments, the low work function material comprises a metal with a melting point greater than or equal to about 400° C., 500° C. or 600° C.

The thickness of the WF layer of some embodiments is less than 2.5 nm. In some embodiments, the WF layer has a thickness less than or equal to 2.0 nm, 1.5 nm or 1.0 nm. In some embodiments, the WF layer has a thickness in the range of 1.0 nm to 1.5 nm.

The work function layer material of some embodiments comprises an element with a negative formation energy for oxide formation. The work function layer material of some embodiments comprises an element with a negative formation energy for nitride formation. The work function layer material of some embodiments comprises an element with a negative formation energy for silicide formation.

The WF layer of some embodiments comprises titanium alloyed, or forming an intermetallic with, one or more of bismuth, indium or zinc.

Some embodiments of the disclosure provide semiconductor devices comprising a low resistance contact. The low resistance contact of some embodiments comprises a work function layer and a metal contact. The work function layer is formed on a silicon layer and the metal contact is formed on the work function layer.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a contact, the method comprising depositing a work function layer comprising a material that does not form a silicide.

2. The method of claim 1, wherein the work function layer comprises titanium and a metal.

3. The method of claim 2, wherein the titanium and the metal form an alloy or an intermetallic.

4. The method of claim 2, wherein the metal comprises bismuth.

5. The method of claim 2, wherein the metal comprises indium.

6. The method of claim 2, wherein the metal comprises zinc.

7. The method of claim 1, wherein the work function layer does not form oxides.

8. The method of claim 1, wherein the work function layer does not form nitrides.

9. The method of claim 1, wherein the work function layer has a melting temperature greater than 500° C.

10. A method of forming a contact, the method comprising depositing a work function layer comprising a material that does not form a silicide, the work function layer comprising titanium and a metal, the titanium and the metal form an alloy or intermetallic; the metal comprising one or more of bismuth, indium or zinc.

11. A semiconductor device comprising a work function layer on a silicon layer; and a metal contact on the work function layer, the work function layer comprising a material that does not form a silicide.

12. The device of claim 10, wherein the work function layer comprises titanium and a metal.

13. The device of claim 11, wherein the titanium and the metal form an alloy or an intermetallic.

14. The device of claim 11, wherein the metal comprises bismuth.

15. The device of claim 11, wherein the metal comprises indium.

16. The device of claim 11, wherein the metal comprises zinc.

17. The device of claim 10, wherein the work function layer does not form oxides.

18. The device of claim 10, wherein the work function layer does not form nitrides.

19. The device of claim 10, wherein the work function layer has a melting temperature greater than 500° C.
